(19) United States
(12) Patent Application Publication
(10) Pub. No.: US 2023/0213702 A1
(43) Pub. Date: Jul. 6, 2023

(54) ARRANGEMENT FOR CONVERTING LIGHT INTO ELECTRICAL ENERGY

(71) Applicant: AUDI AG, Ingolstadt (DE)

(72) Inventors: Tobias MOLL, Ingolstadt (DE); Johannes SCHEUCHENPFLUG, Baar-Ebenhausen (DE); Annegret MATTHAI, Rohrbach (DE)

(73) Assignee: AUDI AG, Ingolstadt (DE)

(21) Appl. No.: 18/001,154

(22) PCT Filed: May 31, 2021
(86) PCT No.: PCT/EP2021/064502

§ 371 Date: Jan. 27, 2023

(30) Foreign Application Priority Data
Jun. 10, 2020 (DE) 10 2020 115 378.3

(51) Int. Cl. G02B 6/26; H01L 31/054; G02F 1/01; B60J 3/04

(52) U.S. Cl. CPC G02B 6/262; B60J 3/04; G02F 1/0102; H01L 31/0547; G02F 2203/48

(57) ABSTRACT

An apparatus is described for converting light of a light source into electrical energy. The apparatus includes a layered body having flat elements, a photovoltaic cell, a light conducting element, a light-switching element , and a photovoltaic cell arranged on a boundary surface of the layered body. The light-switching element (16) can be set to either transmit or block light, In the case of blocking, the light-switching element couples light into the photovoltaic cell t to convert received light into electric energy.

### TECHNICAL BACKGROUND

The present disclosure relates to an arrangement for converting light into electrical energy and a method for converting light into electrical energy.

### BACKGROUND

DE 203 20 919 U1 describes a cover with a glass pane and electrical functional elements.

A solar roof for a motor vehicle is described in document DE 10 2010 003 745 A1.

An energy-autonomous dimmable window is known from publication US 2008/230653 A1.

### BRIEF DESCRIPTION OF DRAWINGS/FIGURES

FIG. 1 shows a schematic representation of an embodiment of the arrangement, according to aspects of the present disclosure.

### DETAILED DESCRIPTION

Against the above background, an object was to either shield against or transmit light from a light source.

This object is achieved by an arrangement and a method with the features of the independent claims. Embodiments of the arrangement and the method emerge from the dependent claims and the description.

The arrangement according to the present disclosure is designed for converting light of a light source into electrical energy and has a plurality of flat elements and at least one photovoltaic cell, for example a solar cell, wherein the flat elements of the arrangement are stacked on top of one another and form a layered body which is delimited and/or enclosed by an entry surface as a boundary surface, for example an entry side, by an exit surface as a boundary surface, for example an exit side, and by at least one outer surface as a boundary surface, for example an outer side. In this case, a main direction is defined, definable and/or to be defined, which is oriented, orientable and/or to be oriented from the entry surface towards the exit surface. The layered body has at least one light-conducting element, usually one light-conducting element, and at least one first light-switching element, generally one first light-switching element, as elements, wherein the at least one light-conducting element is arranged in front of the at least one first light-switching element in the main direction, or wherein the at least one first light-switching element is arranged behind the at least one light-conducting element in the main direction. The at least one photovoltaic cell or a photovoltaic module of the arrangement is arranged on at least one boundary surface. The at least one first light-switching element can be set or is to be set and/or is switchable and/or to be switched to be either light-transmissive in the main direction or light-blocking, for example light-reflecting, counter to the main direction, wherein, for example, a surface of the at least one first light-switching element which is settable and/or switchable to be light-transmissive or light-blocking, for example light-reflecting, faces the at least one light-conducting element. In a case in which the at least one first light-switching element is set, for example, is switched, to be light-transmissive, the at least one first light-switching element is designed to transmit light in the main direction, and in a case when the at least one first light-switching element is set, for example, is switched, to be light-blocking, for example light-reflecting, the at least one first light-switching element is designed to couple, for example to reflect, light to the at least one light-conducting element or into the at least one light-conducting element, for example, i.e. to reflect light back into the at least one light-conducting element counter to the main direction. In this case, the at least one light-conducting element is designed to guide light which is or has been coupled by the at least first light-switching element or reflected by the latter into the at least one light-conducting element counter to the main direction, in a secondary direction which is oriented perpendicular to the main direction to the at least one photovoltaic cell on the at least one boundary surface, for example outer surface. The at least one photovoltaic cell is designed to convert received light into electrical energy.

The entry surface, for example entry side, and the exit surface, for example exit side, can be arranged parallel to one another in an optional embodiment. The at least one photovoltaic cell is arranged, for example, at or on the at least one boundary surface designed as an outer surface, that is to say, depending on the definition, laterally at or on the boundary surface formed as the entry surface, that is to say, depending on the definition, above, and/or at or on the boundary surface formed as an exit surface, that is to say, depending on the definition, below.

The at least one first light-switching element, which is arranged in the main direction behind or, depending on the definition, e. g., under the light-conducting element or light conductor, or a corresponding settable, for example switchable, layer, depending on the application, can not only serve to couple light back into the light-conducting element, usually counter to the main direction, but may also simply block only light and thus largely prevent it from passing through the layered body, which is possible, for example, by absorption and/or reflection of the light. This is advantageous, for example, if an application in a roof of a vehicle is provided for the arrangement. In this case, the entry surface faces the surroundings of the vehicle in which the light, for example from the sun, enters the arrangement from the surroundings. Since a large part of solar radiation is not coupled into the light-conducting element, this passes through the light-conducting element and thus through the arrangement, which is designed or to be referred to as a panorama roof, for example, and thus also through the exit surface and into an interior of the vehicle. This is also desired for illuminating the interior. However, too much light or radiation can arrive in the interior space and the interior can be brightened and/or heated too much. In this case, darkening, i.e. reduction of the light or radiation by the arrangement, is provided and desirable. This can be implemented, for example, with an electrochromic layer, an LC layer or a lucent connector layer or optical waveguide layer or liquid crystal display layer as a possible light-switching element. Such a light-switching element is actively switchable or to be switched, for example actively controlled, wherein a current is supplied to the active light-switching element. In this case, a user, for example an occupant of the vehicle, can set and/or switch the at least one light-switching element to be light-transmissive or light-inhibiting depending on preference and/or depending on the requirement. The at least one light-switching element can be darkened with, for example, controlled activation, wherein light is blocked. A dark, for example black, LC layer absorbs a large part of the light here. A function request, namely darkening and/or reducing of a light load and/or radiation exposure, is thus provided independently of a possible reflection and/or coupling of light into the light-conducting element or into the light conductor, and is thus fulfilled. Alternatively or additionally, it is possible for the at least one light-switching element or a corresponding layer to be designed to be passive, for example thermochromic and/or photochromic. In this case, the at least one light-switching element can set, for example switch,automatically or autonomously, and thus darken as required. In this case, the at least one light-switching element is either light-transmissive or light-blocking depending on a temperature or an intensity and/or frequency of the light. Here, in the case of a high temperature, it can be set to be light-blocking and in the case of a low temperature set to be light-transmissive. Alternatively or additionally, in the case of a high light intensity, it can be set to be light-blocking and in the case of a low light intensity set to be light-transmissive.

With this light-switching element as an additional layer in the main direction behind the light-conducting element, two different functions can be realized depending on the design, namely a reduction of the penetrating light or corresponding radiation and an additional coupling of the light into the light-conducting element. Here, the light-switching element acts to darken the interior through reflection and at the same time increases coupling of the light into the light-conducting element. In one embodiment, a plurality of light-switching elements or corresponding settable and/or switchable layers can be used to perform the provided functions, wherein, for example, a first light-switching element reflects light back counter to the main direction and a further, second light-switching element, which is arranged below or behind in the main direction, can additionally block and/or absorb light. A scattering and/or filtering property of a light-switching element can also be provided, wherein a corresponding light-switching element is designed to distribute light diffusely, wherein, for example, light that is less hard, for example, high-frequency and/or very intense light, enters the interior of the vehicle, and causes shadowing, but instead a more diffuse light distribution takes place. This can be pleasant for the passenger of the vehicle and also offer privacy, since no clear view into the interior space is provided from the outside.

In one embodiment, the at least one light-conducting element and the at least one first light-switching element are arranged directly next to one another and/or adjacent to one another in the main direction, wherein the at least one first light-switching element, in particular the surface of the at least one light-switching element that is usually switchable, i.e. light-transmissive or light-blocking, for example light-reflecting, contacts the at least one light-conducting element.

As at least one further element, the arrangement can have at least one second light-switching element, usually a second light-switching element, which is arranged in front of the at least light-conducting element in the main direction, wherein the at least one light-conducting element is arranged in the main direction between the at least one second light-switching element and the at least one first light-switching element. The at least one second light-switching element is light-transmissive in the main direction and counter to the main direction either light-transmissive or light-blocking, for example can be set, for example switched, to be light-reflecting, light-scattering, light-filtering and/or light-absorbing, wherein the at least one second light-switching element is designed to transmit light from the light source in the main direction and to couple it into the light-conducting element, for example to reflect or specularly reflect, in the case in which the at least one second light-switching element is set, for example switched, to be light-blocking. However, it is also possible for the at least one second light-switching element to be permanently light-transmissive in the main direction and permanently light-blocking, for example light-reflecting, counter to the main direction.

In one embodiment, the at least one second light-switching element and the at least one light-conducting element are arranged directly next to one another and/or adj acent to one another in the main direction, wherein a surface of the at least one second light-switching element which can be set, for example switched, to be light-transmissive or light-reflecting, touches the at least one light-conducting element, wherein the at least one light-conducting element can be arranged in the main direction directly between the at least one second light-switching element and the at least one first light-switching element.

It is possible for at least one coupling element for light to be assigned to the at least one light-conducting element, wherein at least the first light-switching element is designed and/or referred to as at least one first coupling element for the at least one light-conducting element and optionally also the at least one second light-conducting element as at least one second coupling element for the at least one light-conducting element and is designed for coupling light into the at least one light-conducting element.

Furthermore, at least one out-coupling element for light can be assigned to the at least one light-conducting element, wherein the at least one out-coupling element is arranged on the at least one boundary surface, for example outer surface, entry surface and/or exit surface, between the at least one light-guiding element and the at least one photovoltaic cell, and is designed for coupling light out of the at least one light-guiding element and optionally for coupling light into the at least one photovoltaic cell or into the at least one photovoltaic module.

The presented arrangement can be designed as a glazing pane for closing an opening in an enclosing surface, for example a wall, wherein the enclosing surface and the arrangement arranged in the opening separate an interior from a surroundings, wherein the entry surface, for example entry side, through which the light enters, is assigned, can be assigned and/or is to be assigned to the surroundings in which a light source, for example the sun, is located, and the exit surface, for example exit side, to the interior, wherein the light source is arranged in the surroundings outside the interior or is located in the surroundings. The arrangement, for example a glazing pane and/or the at least one light-conducting element, can be used for a roof of a vehicle which separates the interior from the surroundings. The at least one photovoltaic cell is arranged laterally on the layered body and thus to the side of the at least one light-conducting element in the roof of the vehicle. The interior space is arranged below the roof with the arrangement integrated therein. If the at least one light-switching element is set, for example switched, to be light-transmissive, light from the surroundings that enters the entry surface passes through the layered body and the at least one light-switching element and thus also the exit surface of the arrangement and is thereby allowed to pass into the interior space. If the at least one light-switching element is alternatively set to be light-blocking and thereby light-reflecting, light from the surroundings, which otherwise exits through the exit surface, will be coupled into the at least one light-conducting element counter to the main direction, be generally reflected and be coupled from there into the at least one photovoltaic cell on the lateral outer surface and converted into electrical energy.

In addition, the arrangement for a vehicle, for example a motor vehicle or car, can be provided and/or designed and can be used, for example, as a glazing pane for the vehicle, wherein the arrangement or a corresponding glazing pane can be arranged in a roof of the vehicle.

The at least one photovoltaic cell is designed as and/or to be referred to as a solar cell and is designed to convert light of the sun as a light source into electrical energy, wherein the at least one photovoltaic cell can be adapted to a frequency spectrum of the sun.

The layered body of the arrangement can, for example, be either cuboid or cylindrical. If the layered body is cuboid, it will be delimited in each case by a rectangular entry surface and exit surface and by four rectangular outer surfaces or lateral surfaces, for example outer sides. In this case, not only the entry surface but also the exit surface in each case have a length and a width depending on the definition. Accordingly, each of the outer surfaces has a height. It is provided here that both the width and the length of the entry and exit surfaces are several times greater than the height of an outer surface in each case. If the layered body is cylindrical, it will be delimited by an entry surface and an exit surface which are both disk-shaped and have a radius. In this case, the layered body is further delimited only by an outer surface, for example, an outer side, which is formed in the shape of a cylinder shell and has a height which is substantially less or smaller than the radius of the entry surface or exit surface. It is also possible for the layered body to have an n-cornered entry and exit surface, wherein the entry surface or exit surface can be n-angular, for example triangular, rectangular or polygonal and can have, in addition to the entry surface and exit surface as boundary surfaces, corresponding n-sided outer surfaces.

The method according to the present disclosure is provided for converting light into electrical energy having an arrangement for converting light into electrical energy, for example with an embodiment of the embodiment of the arrangement presented above, which has a plurality of flat elements and at least one photovoltaic cell, for example a solar cell, wherein the flat elements are layered one above the other and form a layered body which is arranged on and/or enclosed by an entry surface as boundary surface and an exit surface as boundary surface, which are both arranged flat and in parallel, for example, and at least one outer side or lateral surface as boundary surface. In this case, a main direction is defined, which is oriented from the entry surface towards the exit surface as a boundary surface. The layered body has at least one light-conducting element, usually one light-conducting element, and at least one first light-switching element, generally a first light-switching element, as elements, wherein the at least one light-conducting element is arranged in front of the at least one first light-switching element in the main direction, or wherein the at least one first light-switching element is arranged in the main direction behind the at least one light-conducting element, wherein the at least one photovoltaic cell is generally arranged on the at least one boundary surface, for example, outer surface. However, it is also conceivable for the at least one photovoltaic cell to be arranged at the entry surface and/or exit surface as a boundary surface. The at least one first light-switching element is set and/or switched in the main direction to be either light-transmissive or counter to the main direction to be light-blocking, wherein a settable surface of the at least one first light-switching element that is usually switchable, i.e. light-transmissive or light-blocking, for example light-reflecting, faces the at least one light-conducting element. In the case in which the at least one first light-switching element is set and/or switched to be light-transmissive, light is transmitted from the at least one first light-switching element. In contrast, in the case in which the at least one first light-switching element is set and/or switched to be light-blocking, for example light-reflecting, light is reflected by the at least one first light-switching element, wherein in this case light which is coupled, for example reflected, by the at least one first light-switching element counter to the main direction into the at least one light-switching element, is guided from the at least one light-conducting element in a secondary direction, which is oriented perpendicular to the main direction, to the at least one photovoltaic cell on the at least one boundary surface, for example outer surface, wherein light which is received by the at least one photovoltaic cell is converted into electrical energy.

In one embodiment, the at least one first light-switching element is set, for example switched, to be light-transmissive when light of the light source is to radiate through the exit surface. Alternatively, the at least one first light-switching element is set, for example switched, to be light-blocking, e. g. light-reflecting, when light from the light source is to be darkened. In this case, it is possible for a degree of transmission and a degree of reflection of the at least one first light-switching element to be set and/or selected quantitatively. In this case, it is conceivable for the degree of transmission of the at least one first light-switching element to be set to be higher than its degree of reflection if it is set to be light-transmissive. If, on the other hand, the at least one first light-switching element is set to be light-blocking, for example light-reflecting, its degree of reflection is set higher than its degree of transmittance. Furthermore, a degree of absorption of the at least one first light-switching element can also be taken into account. In this case, the at least one light-switching element can have a low degree of absorption if it is set to be light-transmissive. Or, it may have a high degree of absorption if it is set to be light-blocking, for example light-reflecting.

Usually, the at least one light-switching element is not settable to be purely light-transmissive, that is to say not 100% light-transmissive or purely light-blocking, that is to say not 100% light-blocking or 0% light-transmissive, since in real applications it can simultaneously be both partially transparent to light and also partially opaque to light. In this case, partially can relate, for example, to a proportion of the spectrum or of the wavelengths of the irradiated light. This means that the at least one light-conducting element is, at the same time, set to a proportion of x% light-transmissive to a proportion of y% light-reflecting, to a proportion of z% light-scattering and to a proportion of w% light-absorbing, wherein w, x, y, z are in each case greater than or equal to zero. In one embodiment of the arrangement and/or of the method, it is provided that, if only two cases or settings, namely “light-transmissive” and “light-blocking” are provided, in the case in which the at least one light-switching element is set to “light-transmissive”, it will be set predominantly or to a large or largest proportion to be light-transmissive, wherein it is light-transmissive to a greater degree than light-blocking. If, on the other hand, the at least one light-switching element is set to “light-blocking”, it will be predominantly or to a larger or largest proportion light-blocking, for example light-reflecting instead of light-transmissive. In an embodiment, the at least one light-conducting element can be set stepwise or continuously between 0% and 100%, depending on the definition, and can be set in a manner that has a light-blocking effect between 100% and 0%.

In an embodiment of the arrangement and/or of the method, it is provided that, in the case in which the at least one first light-switching element is set, for example is switched, to reflect light, a first portion of light of the light source will be reflected by the at least one first light-switching element in the direction of the at least one light-conducting element, and a second portion of the light of the light source will be transmitted, wherein the first reflected portion of the light will be greater than the second transmitted portion of the light. In contrast, if the at least one first light-switching element is set, for example switched, to be light-transmissive, the first portion of the light of the light source which is reflected by the at least one first light-switching element counter to the main direction will be smaller than the second portion of the light of the light source which is transmitted by the at least one first light-switching element.

Depending on the definition, the presented arrangement can be designed as or referred to as a transparent pane having at least one photovoltaic cell, wherein the pane with the at least one first light-switching element has a layer which can be set or switched to be light-transmissive or light-blocking, depending on the requirement, for example.

In this case, it is possible for the at least one light-conducting element and the at least one first and possibly the at least one second light-conducting element to be designed to be flexible and thus deformable. The at least one first light-switching element can also be set and/or switched to be a settable, for example switchable layer, either absorbing, filtering and/or transmitting or reflecting. If the at least one first light-switching element is designed to be absorbent or reflective, it will thereby be possible to switch off light from the light source. If the at least one first light-switching element is set to be reflective and is effective, an additional coupling of light into the at least one light-conducting element or into a corresponding light conductor will be possible.

The arrangement can have one or more photovoltaic cells on the at least one boundary surface, i.e. on the outer surface or lateral surface and possibly also on the entry surface or exit surface. A coupling element or a plurality of coupling elements and thus the at least one light-switching element can be assigned as at least one coupling element to the at least one light-conducting element or at least one light conductor. The at least one coupling element can have, for example, a refractive or light-refractive or a diffractive or light-scattering surface structure, i.e. as a diffractive optical coupling element (DOE) or light-switching element, for example as a holographic optical element (HOE), for example as a volume hologram. Such a diffractive optical element, for example a holographic optical element, can be n-cornered or round.

In addition, an out-coupling element or a plurality of out-coupling elements can be assigned to the light conductor. At least one such out-coupling element can have a refractive or diffractive surface structure. It is also possible for the at least one out-coupling element to be designed as a diffractive optical element, for example as a holographic optical element, for example as a volume hologram. The at least one light-switching element or the at least one light conductor can be designed in one or more layers, wherein the layered body of the arrangement accordingly has a light-conducting element or a plurality of light-conducting elements, wherein the at least one light-switching element, i.e. at least the at least one first light-switching element and optionally at least one second light-switching element, is/are embedded in the layered body. In this case, the at least one first light-switching element and optionally also the at least one second light-switching element can be embedded within the layered body between two directly adjacent light-conducting elements.

The at least one light-switching element or coupling element for light can set or switched to be absorbing, filtering and/or reflective or scattering and/or transmissive. In this case, it is possible that a respective switching or setting of the at least one light-switching element or coupling element for light, can be set, for example switched, segmentedly, pixel-precisely or selectively. The at least one light-switching element can be electrochromic, photochromic or thermochromic, for example, and/or can be designed or designated as a liquid crystal display (LCD) or as tintable glass (PDLC glass or liquid crystal or polymer-dispersed liquid crystal). However, the at least one light-switching element or coupling element for light can also be set statically or fixedly or invariably and can have at least one of the aforementioned optical properties and accordingly be in each case partially absorbent, filtering, reflective, scattering and/or light-transmissive and accordingly predominantly or partially fixedly or permanently, in particular predominantly absorbent, filtering, reflective, scattering or light-transmissive.

It is possible for the at least one light-switching element to be transparent or light-transmissive, or reflective or specularly reflective and/or absorbent for certain wavelengths of the light, for example for wavelengths of the light of the sun.

The presented arrangement can be installed, for example, in the roof as an enclosing surface or wall of the vehicle. If the at least one first light-switching element is set to be transmissive, it is possible for light or radiation from the sun as light source, which is transmitted through the arrangement, to be so intense that occupants in the interior of the vehicle perceive the light as too bright and/or for the interior to thus be able to heat up a great deal. In order to prevent this and thus to mask out or hide the light source, the at least one first light-switching element is set to be reflective, wherein light which is coupled into the at least one light-conducting element by the at least one first light-switching element is directed onto the at least one photovoltaic cell and is thereby converted into electrical energy. It is also possible for the arrangement to have a plurality of first light-switching elements which are arranged behind the at least one light-conducting element in the main direction. In this case, for example, only one of these light-switching elements can be set, for example switched, to be variably light-transmissive or light-blocking, whereas a further light-switching element is set to be fixedly or permanently light-blocking or light-transmissive. Such a light-switching element or coupling element can be designed as a holographic optical element. In this case, a simple realization of the presented arrangement is obtained by combining a fixed light-switching element and a light-switching element which is variably settable and/or switchable to be light-transmissive or light-blocking, wherein a coupling of light through the fixedly set light-switching element is independent of a function of the light-switching element which is still variable and/or dynamically settable, for example switchable, that is, irrespective of whether it is now set, for example switched, to be light-transmissive or light-blocking, as a result of which a coupling of light into the at least one light-conducting element and a generation of electrical current are not influenced.

With the arrangement it is possible not only to darken light of the light source but also to capture and convert it into electrical energy. Correspondingly, a darkening and a supply of the at least one photovoltaic cell with light is possible simultaneously with the arrangement. The at least one photovoltaic cell is arranged on the at least one boundary surface, for example, outer surface, and thus usually on the edge of the arrangement and is thus protected. With the at least one first light-switching element it is possible to also couple infrared light or ultraviolet light of the sound source into the at least one light-conducting element. The layered body of the arrangement can be delimited by a frame or an edge, wherein the at least one photovoltaic cell can be installed in the frame and thus protected.

With the arrangement, a darkening of the light source is thus possible, whereby a pleasant visual effect can be brought about. In addition, an unnecessary heating of the interior of the vehicle can thereby be avoided. Furthermore, scattering of light from the light source is also possible, wherein a visually pleasant, shadow-free natural illumination of the interior of the vehicle can be created. In addition, the arrangement makes it possible to prevent glare for the occupants of the vehicle. Furthermore, privacy of the occupants can also be ensured by the arrangement. If the at least one first light-switching element is set to be scattering or reflective, an additional coupling of light or radiation into the at least one light-conducting element will be possible, which otherwise penetrates unhindered when the at least one first light-switching element is designed to be transmissive. An efficiency of an illumination or irradiation of the at least one photovoltaic cell can thus be increased.

It is understood that the features mentioned above and those still to be explained below can be used not only in the respectively specified combination but also in other combinations or alone without departing from the scope of the present disclosure.

The present disclosure is schematically illustrated in the drawing by means of embodiments and is described schematically and in detail with reference to the drawing.

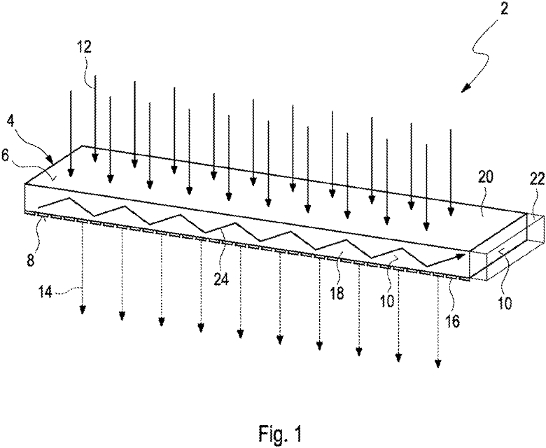

FIG. 1 shows a schematic representation of an embodiment of the arrangement according to aspects of the present disclosure.

The embodiment of the arrangement 2 according to the disclosure shown schematically in FIG. 1 has a layered body 4 which is cuboid in this case and is delimited by an entry surface 6, for example entry side, in FIG. 1 at the top, an exit surface 8, for example exit side, at the bottom in FIG. 1, and of a total of four outer surfaces 10, for example outer sides, wherein the entry surface 6, the exit surface 8 and the outer surfaces 10 can be designed and/or referred to as boundary surfaces of the layered body 4. In addition, FIG. 1 shows solid arrows 12 above the layered body 4 and dashed arrows 14 below the layered body 4. In this case, all arrows 12, 14 indicate a main direction which is oriented and/or aligned here from the entry surface 6 in the direction of the exit surface 8.

Furthermore, the layered body 4 has a plurality of elements, namely here a first light-switching element 16, a light-conducting element 18, and optionally a second light-switching element 20 additionally provided here, wherein the first light-switching element 16 is arranged between the exit surface 8 and the light-conducting element 18. In addition, the second light-switching element 20 is arranged between the light-conducting element 18 and the entry surface 6. The second light-switching element 20 is, however, transmissive for light of a light source which impinges on the arrangement 2 in the main direction according to the solid arrows 12, but transmits light which radiates reflectively counter to the main direction from the light-conducting element 18 onto the second light switching element 20, wherein such light which is reflected by the second light-switching element 20 is radiated again in the main direction into the light-conducting element 18. In addition, a photovoltaic cell 22 or a photovoltaic module is arranged here at or on an outer surface 10, which laterally delimits the layered body 4 depending on the definition. Furthermore, it is also possible for such a photovoltaic cell 22 to be arranged at or on the entry surface 8, depending on the definition, above and/or at or on the exit surface 10, depending on the definition, below. The light is usually reflected by the first light-switching element 16 into the light-conducting element 18 and thus coupled in. Light which is reflected by the first light-switching element 16 counter to the main direction into the light-conducting element 18 and crosses the latter counter to the main direction can by the second light-switching element 20 optionally provided here be reflected back again in the main direction and thus the light be prevented from leaving the arrangement 2 through the entry surface 6 again, wherein by combining both light-switching elements 16, 20 more light in the light-conducting element 18 between the light-switching elements 16, 20 is bundled or transported to the photovoltaic cell 22 and converted by the latter into electrical energy.

The first light-switching element 16 can be set to be either transmissive or reflective for light which radiates onto the first light-switching element 16 in the main direction. If the first light-switching element 16 is set to be transmissive of the light in the main direction, this light will be transmitted or let through the first light-switching element 16. If, on the other hand, the first light-switching element 16 is set to be reflective or specularly reflective, light which impinges on the first light-switching element 16 in the main direction after it has previously crossed the light-conducting element 18 will be reflected back or coupled into the latter.

FIG. 1 also shows a zigzag arrow 24, which is assigned here to the light-conducting element 18. This zigzag arrow 24 indicates a movement of light of the light source which, in the case in which the first light-switching element 16 is set to be reflective or specularly reflective, will be reflected back and forth within the light-conducting element 18 between the two light-switching elements 16 and 20 and is further directed perpendicular to the main direction to the photovoltaic cell 22 and is coupled into the photovoltaic cell 22, wherein radiation energy of the light is converted from the photovoltaic cell 22 into electrical energy.

Thus, the light in the light-conducting element 18 and thus in a corresponding light conductor is collected and coupled out of the light-conducting element 18 at at least one outer surface 10 and is further coupled into the photovoltaic cell 22. The first light-switching element 16 can be set, for example switched, to be absorbent, scattering or reflective. In one possible realization, at least one light-switching element 16, 20 is never completely transparent or light-blocking. As a rule, it is light-transmissive in a first percentual proportion and light-blocking in a second percentual proportion. If the at least one light-switching element 16, 20 in one embodiment is set to be light-transmissive, for example switched, the first percentual proportion in which it is light-transmissive, will be greater than the second percentual proportion in which it is light-blocking. If, on the other hand, it is set, for example switched, to be light-blocking, the second percentual proportion in which it is light-blocking will be greater than the first percentual portion in which it is light-transmissive.

REFERENCE SIGNS:

| | |
|---|---|
| 2 | Arrangement |
| 4 | Layered body |
| 6 | Entry surface |
| 8 | Exit surface |
| 10 | Outer surface |
| 12 | Solid arrow |
| 14 | Dashed arrow |
| 16 | First light-switching element |
| 18 | Light-conducting element |
| 20 | Second light-switching element |
| 22 | Photovoltaic cell |
| 24 | Zigzag arrow |

1-10. (canceled)

11. An apparatus for converting light of a light source into electrical energy, said apparatus comprising:
a layered body formed by a plurality of flat elements, wherein the flat elements are stacked on top of one another, wherein the layered body is delimited by an entry surface, an exit surface and at least one outer surface as boundary surfaces, wherein a main direction is defined as being oriented from the entry surface towards the exit surface, and wherein the layered body further includes:
at least one first light-switching element, and
at least one light-conducting element that is located in front of the at least one first light-switching element in the main direction;
at least one photovoltaic cell arranged on at least one boundary surface of the layered body, wherein the at least one first light-switching element can be set to either transmit or block light,
wherein in the case in which the at least one first light-switching element is set to transmit the light, the at least one first light-switching element is set to transmit the light, and
wherein in the case in which the at least one first light-switching element is set to block the light, the at least one first light-switching element is configured to couple the light into the at least one light-conducting element, wherein the at least one light-conducting element in this case is configured to transmit the light which has been coupled-in by the one first light-switching element to the at least one photovoltaic cell on the at least one boundary surface, and wherein the at least one photovoltaic cell is configured to convert received light into electric energy.

12. The apparatus according to claim 11, wherein the at least one light-conducting element and the at least one first light-switching element are arranged directly next to one another in the main direction, wherein the at least one first light-switching element contacts the at least one light-conducting element.

13. The apparatus according to claim 11, having as at least one further element at least one second light-switching element arranged in front of the at least one light-conducting element in the main direction, wherein the at least one light-conducting element is arranged in the main direction between the at least one second light-switching element and the at least one first light-switching element, wherein the at least one second light-switching element is light-transmissive in the main direction and light-blocking counter to the main direction, wherein the at least one second light-switching element is configured to transmit the light in the main direction and to couple it into the at least one light-conducting element counter to the main direction.

14. The apparatus according to claim 11, wherein at least one coupling element for light is assigned to the at least one light-conducting element, wherein at least the first light-switching element is designed as at least one first coupling element for the at least one light-conducting element and is configured to couple the light into the at least one light-conducting element.

15. The apparatus according to claim 11, wherein at least one out-coupling element for light is assigned to the at least one light-conducting element, said out-coupling element being arranged at least on the at least one boundary surface between the at least one light-conducting element and the at least one photovoltaic cell and being configured for coupling the light out of the at least one light-conducting element and into the at least one photovoltaic cell.

16. The apparatus according to claim 11, designed as a glazing pane for closing an opening in an enclosing surface, wherein the enclosing surface and the arrangement arranged in the opening separate an interior from a surroundings, wherein the entry surface of the surroundings and the exit surface can be assigned to the interior, wherein the light source is arranged in the surroundings outside the interior.

17. The apparatus according to claim 11, which is configured for a vehicle.

18. The apparatus according to claim 11, wherein the at least one photovoltaic cell is arranged on at least one boundary surface of the layered body formed as an outer surface.

19. A method for converting light of a light source into electrical energy, the method comprising:
setting at least one first light-switching element to either transmit or block the light, the at least one first light-switching element forming a part of a layered body, the layered body being further formed by a plurality of flat elements, wherein the flat elements are stacked on top of one another, wherein the layered body is delimited by an entry surface, an exit surface and at least one outer surface as boundary surfaces, wherein a main direction is defined as being oriented from the entry surface towards the exit surface, and wherein the layered body further includes the at least one light-conducting element that is located in front of the at least one first light-switching element in the main direction;
when the at least one first light-switching element is set to transmit the light, transmitting the light;
when the at least one first light-switching element is set to block the light, coupling the light by the at least one first light-switching element into the at least one light-conducting element;
transmitting, by the at least one light-conducting element, the light which has been coupled-in by the one first light-switching element to an at least one photovoltaic cell on the at least one boundary surface of the layered body; and
converting, by the at least one photovoltaic cell, the light into electric energy.

20. The method according to claim 19, further comprising:
setting the at least one first light-switching element to transmit the light when the light of the light source is desired to radiate through the exit surface; and
setting the at least one first light-switching element to be light-blocking when the light of the light source is to be darkened.
